(19) United States
(12) Patent Application Publication
(10) Pub. No.: US 2010/0119345 A1
(43) Pub. Date: May 13, 2010

(54) Position-returning mechanism for a pick-and-place apparatus

(75) Inventors: Chiu-Fang ` Chang, Hsinchu (TW); Pei-Luen Hsu, Hsinchu (TW)

Correspondence Address: BACON & THOMAS, PLLC, 625 SLATERS LANE, FOURTH FLOOR, ALEXANDRIA, VA, 22314-1176, US

(73) Assignee: King Yuan Electronics Co., Ltd., Hsinchu (TW)

(21) Appl. No.: 12/458,614

(22) Filed: Jul. 17, 2009

(30) Foreign Application Priority Data
Nov. 11, 2008 (TW) 097143459

(51) Int. Cl. H01L 21/673

(52) U.S. Cl. 414/752.1; 414/749.1

(57) ABSTRACT

A position-returning mechanism for a pick-and-place apparatus is disclosed, in which three first circular recesses are respectively concavely provided and three fixing blocks are respectively convexly provided in an equal angle along an outer periphery on a lower surface of a fixing base, and each of the three first circular recesses is inserted and disposed between two adjacent fixing blocks. A movable base is correspondingly installed on the lower part of the fixing base. Three corresponding second circular recesses are concavely provided and three recesses are provided on an upper surface of the movable base. Three ring sprig pillars are provided and received respectively in the corresponding first circular recesses and the corresponding second circular recesses. Therefore, according to the invention, the movable base is allowed to provide functions of radial displacement and axial rotation relative to the fixing base via the three ring sprig pillars.

### BACKGROUND OF THE INVENTION

1. Field of the Invention

The present invention relates to a position-returning mechanism and, more particularly, to a position-returning mechanism for a pick-and-place apparatus.

2. Description of Related Art

In the conventional art, all machines or equipments involving an operation of moving or positioning require a position-returning mechanism to proceed with buffering and to assist positioning. Such a requirement is particularly required in the industry of semiconductor, package test and precise machine, which needs high precision.

The position-returning mechanism commonly seen in the conventional art is shown in FIG. 5. The conventional position-returning mechanism includes a screw spring 93, a steel ball 92 and a positioning base 91. One end of the screw spring 93 connects against a fixing surface (not shown in the drawing), and the other end is configured to dispose the steel ball 92. A circular recess 911 is concavely provided on an upper surface of the positioning base 91 and a part of the steel ball 92 is received in the circular recess 911. The operating principle is as follows. As the screw spring 93 generate a radial displacement due to a radial force, a part of the steel ball 92 moves out of the circular recess 911. As the force causing the displacement is removed, the spring force of the screw spring 93 urges the steel ball 92 to fall back into the circular recess 911, thereby producing position-returning mechanism.

Base on this, though the conventional position-returning mechanism achieves the effect of position-returning, it is uneasy to assemble and maintain, and further, the cost is higher. In addition, the circular recess 911 on the upper surface of the positioning base 91, or the steel ball 92 is easily subject to serious wearing out due to long time usage, such that the normal effect cannot be shown. On the other hand, the screw spring 93 is also an important factor to affect the ability of position-returning. If an improper screw spring 93 is adopted, it is easy to produce insufficient returning force, or no effect can be produced, if the spring force is too big, which even causes damage to the machinery parts.

Therefore, it is desirable to provide an improved position-returning mechanism for a pick-and-place apparatus, capable of providing simple structure, low cost, ease of assembling and maintaining, and long time use.

### SUMMARY OF THE INVENTION

The present invention is directed to a position-returning mechanism for a pick-and-place apparatus, comprising a fixing shaft base, a fixing base, a movable base, at least two ring sprig pillars and a shaft rod. The fixing shaft base includes a fixing portion. The fixing base is installed beneath the fixing shaft base and provides a centering through hole, in which at least two first circular recesses are respectively concavely provided in an equal angle along an outer periphery of the centering through hole on a lower surface of the fixing base. In addition, at least two fixing blocks are respectively convexly provided in an equal angle on the lower surface of the fixing base, respectively each of the at least two fixing blocks is disposed and inserted between two adjacent first circular recesses, an axial buffer unit is provided and received in an internal part of each of the at least two fixing blocks, and the axial buffer unit is convexly extending downward to an external part of each of the fixing blocks.

Further, the movable base is installed with a centering shaft hole, in which at least two second circular recesses are concavely provided on an upper surface of the movable base corresponding to the at least two first circular recesses of the fixing base. In which at least two recessing portions are hollowed out and concavely provided at the movable base corresponding to the at least two fixing blocks of the fixing base, and the at least two recessing portions are respectively bigger than the corresponding at least two fixing blocks. Further, the at least two ring sprig pillars are provided and received respectively in the at least two first circular recesses and in the at least two second circular recesses.

Still further, the shaft rod includes a head portion and a tail portion. The head portion is hooked against a lower surface of the movable base, and the trail portion is pierced through the centering shaft hole and the centering through hole and is fixed and installed on the fixing portion of the fixing shaft base, such that the fixing base and the movable base are interposed between the head portion and the fixing shaft base and maintained to space apart an axial gap each other for slight movement in an axial direction. In addition, the diameter of the tail portion of the shaft rod is smaller than the centering shaft hole of the movable base and maintains to space apart a radial gap each other, such that the movable base can make slight radial movement laterally or slight coaxial rotation. Therefore, the invention is capable of providing position-returning functions of radial displacement, axial displacement and axial rotation.

According to the invention, the shaft rod may be a screw rod, the fixing portion of the fixing shaft base is an inner screw hole and the screw rod is correspondingly screwed and fixed in the inner screw hole, whereby the screw rod can link and be configured to install the fixing base and the movable base. The invention further comprises at least a bearing, which is installed between the fixing base and the movable base, for reducing wearing away and friction force between the fixing base and the movable base when in movement or rotation.

Besides, each of the at least two ring spring pillars is a hollow spring pillar surrounded and joined together by two ends of a steel strip, a hollow spring pillar surrounded and sealed tightly by two ends of a steel strip, a hollow spring pillar surrounded openly but not connected by two ends of a steel strip, a screw spring pillar screwed and surrounded from a center by a steel strip, or an equivalent spring pillar appearing in other forms.

In the invention, a mechanical arm is further installed on an upper surface of the fixing base and the fixing shaft base is installed on a lower part of the mechanical arm, thereby providing the functions of movement and rising and descending of the entire position-returning mechanism. In addition, the lower surface of the movable base is further installed with a guiding base and the guiding base includes at least a guiding hole. Through the guiding hole of the guiding base incorporated with a guiding pillar of a test base, precise positioning can be made. Furthermore, a lower surface of the guiding base further provides a vacuum sucking head for proceeding with sucking and placing a chip or other objects.

Other objects, advantages, and novel features of the invention will become more apparent from the following detailed description when taken in conjunction with the accompanying drawings.

### BRIEF DESCRIPTION OF THE DRAWINGS

FIG. 1 is a schematic diagram of the entire equipment according to a preferred embodiment of the invention;

FIG. 2 is an exploded view of a position-returning mechanism according to a preferred embodiment of the invention;

FIG. 3 is a cross-sectional view of a position-returning mechanism according to a preferred embodiment of the invention;

FIG. 4A to 4D are each a schematic diagram of a ring sprig pillar according to a preferred embodiment of the invention;

FIG. 5 is a schematic diagram of a conventional position-returning mechanism.

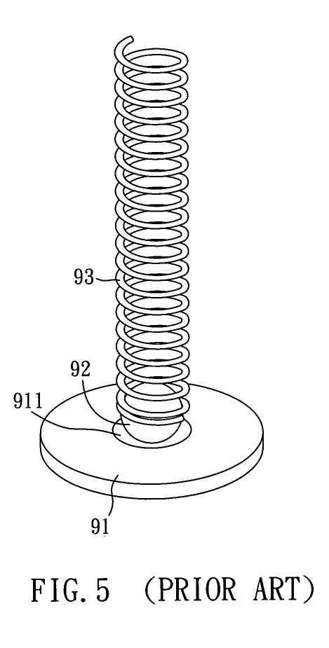

### DETAILED DESCRIPTION OF THE PREFERRED EMBODIMENT

The detail of the invention will be explained with a pick-and-place apparatus for carrying a chip in a semiconductor package test industry. However, the invention should not be limited to such an equipment or industry, but may be applied to any machine or equipment requiring precise positioning, position-returning or buffering.

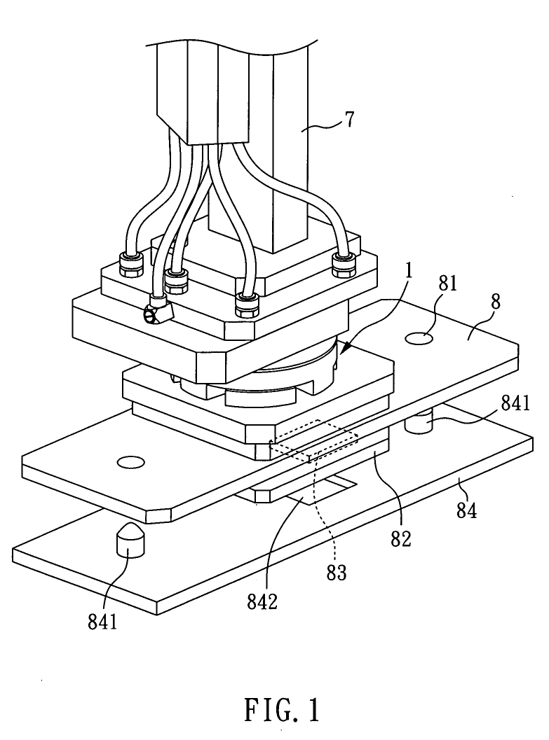

With reference to FIG. 1, there is shown a schematic diagram of the entire equipment according to a position-returning mechanism for a pick-and-place apparatus of a preferred embodiment of the invention. The drawing shows an apparatus for carrying a chip in a chip package test process, in which it is illustrated a test base 84, and a chip inserting slot 842 is provided in the center of the test base. The apparatus is mainly used to test whether the chip is in a normal operation, or to test related parameters of the chip. Each of two ends of the test base 84 provides convexly a guiding pillar 841.

Further, on an upper side of the test base 84, it shows a vacuum sucking head 82, mainly used for sucking and placing a chip 83. A guiding base 8 is provided on an upper surface of the vacuum sucking head 82 and used for installing the vacuum sucking head 82. Each of two ends of the guiding base 8 is provided with a guiding hole 81, which corresponds to a guiding pillar 841. As the vacuum sucking head 82 reaches a position to be ready for descending and placing the chip 83 to the chip inserting slot 842, the chip 83 will be placed precisely in the chip inserting slot 842 via insertion matching of the guiding pillar 841 and the guiding hole 81.

In addition, the drawing shows a mechanical arm 7, providing the functions of movement and rising and descending of the entire equipment. The mechanical arm 7 is connected with a position-returning mechanism 1 and a lower part of the mechanical arm 7 is connected to the guiding base 8. However, as the vacuum sucking head 82 is descending and ready for sucking and placing the chip 83, it inevitably produces displacement deviation resulting from error of machine parts or long time use, rendering incapableness of precise positioning. The position-returning mechanism 1 is able to absorb error and produce buffer, i.e. providing displacement tolerance in a radial direction and an axial direction, and providing tolerance of rotational tolerance, thereby allowing the guiding hole 81 to be smoothly inserted into the guiding pillar 841. As the guiding base 8 rises, the guiding hole 81 is departed from the guiding pillar 841 and then the position-returning mechanism 1 provides position returning, i.e. returning to the position of the original shaft center so as to be adapted to deviation error of different test bases 84.

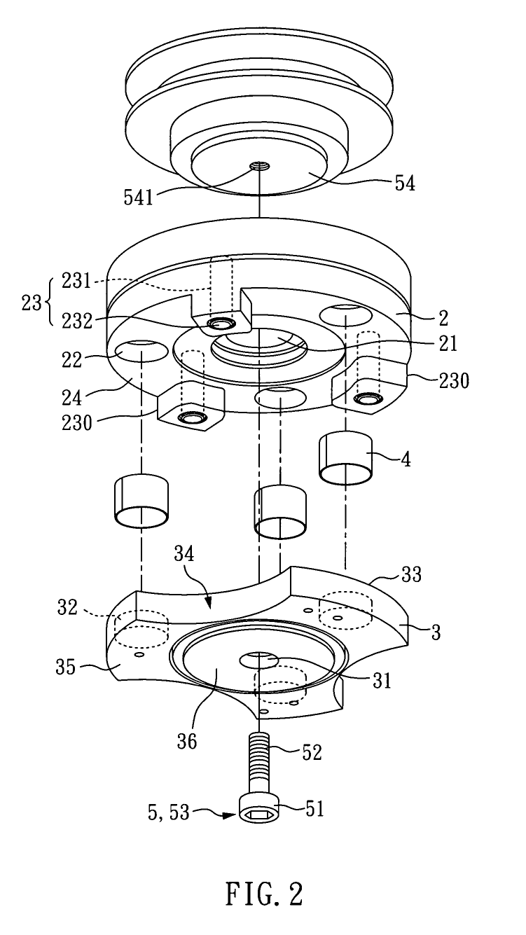

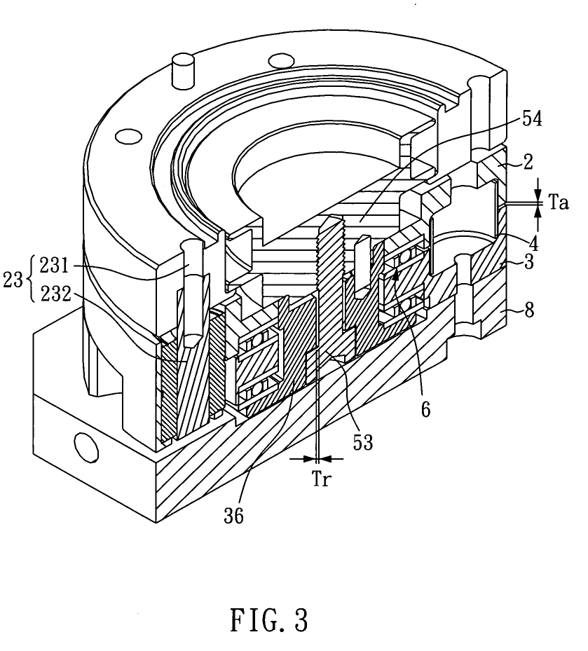

Please refer to FIG. 2 together with FIG. 3. FIG. 2 is an exploded view of a position-returning mechanism 1 according to a preferred embodiment of the invention and FIG. 3 is a cross-sectional view of the position-returning mechanism 1 according to the preferred embodiment of the invention. As shown, a fixing shaft base 54 includes a fixing portion 541, which is an inner screw hole. A fixing base 2 is installed beneath the fixing shaft base 54 and provides a centering through hole 21, in which three first circular recesses 22 are respectively concavely provided in an equal angle along an outer periphery of the centering through hole 21 on a lower surface 24 of the fixing base 2. In addition, three fixing blocks 230 are respectively convexly provided in an equal angle on the lower surface 24 of the fixing base, in which each of the three fixing blocks 230 is disposed and inserted between two adjacent first circular recesses 22.

A shaft buffer unit 23 is provided and received in an internal part of each of the three fixing blocks 230, and the shaft buffer unit 23 is convexly extending downward to an external part of each of the fixing blocks 230. According to the embodiment, the shaft buffer unit 23 includes an air pressure guiding pillar 231 and a sliding sleeve 232. The air pressure guiding pillar 231 is filled with high pressure gas and the sliding sleeve 232 is slid and provided in the air pressure guiding pillar 231 and protruded from the lower surface 24 of the fixing base 2. The high pressure gas in the air pressure guiding pillar 231 is capable of supporting the sliding sleeve 232, thereby producing buffer force in a axial direction.

Further, as shown, a movable base 3 is installed with a movable shaft base 36, and a centering shaft hole 31 is provided in the center of the movable shaft base 36. Three second circular recesses 32 are concavely provided on an upper surface 33 of the movable base 3 corresponding to the three first circular recesses 22 of the fixing base 2. Three recessing portions 34 are hollowed out and concavely provided at the movable base 3 corresponding to the three fixing blocks 230 of the fixing base 2, and the three recessing portions 34 are respectively bigger than the corresponding one of the fixing blocks 230. The recessing portions 34 are to receive the fixing blocks 230 so as to allow the shaft buffer unit 23 of each of the fixing blocks 230 to support the guiding base 8 beneath thereof.

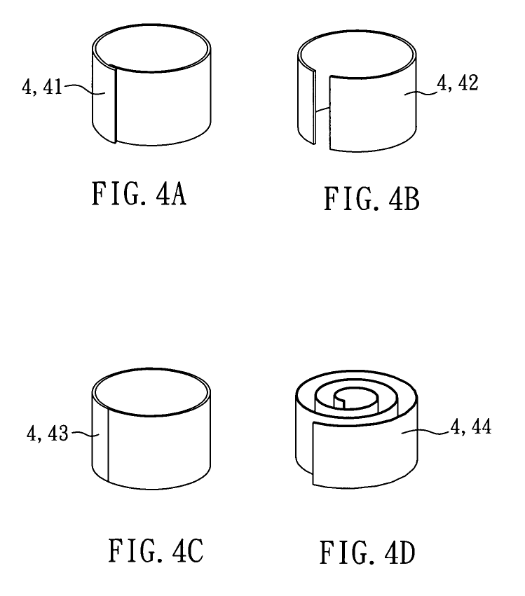

Further, three ring sprig pillars 4 are provided and received in the corresponding three first circular recesses 22 and in the three second circular recesses 32. According to the embodiment, each of the ring spring pillars 4 is a hollow spring pillar 41 surrounded and joined together by two ends of a steel strip, as shown in FIG. 4A. Of course, each of the ring spring pillars 4 may be a hollow open spring pillar 42 surrounded openly but not connected by two ends of a steel strip, as shown in FIG. 4B, a hollow sealing spring pillar 43 surrounded and sealed tightly by two ends of a steel strip, as shown in FIG. 4C, or a screw spring pillar 44 screwed and surrounded from a center by a steel strip, as shown in FIG. 4D.

Please refer to FIGS. 2 and 3 continuously. As shown, according to the embodiment, a shaft rod 5 is a screw rod 53 and includes a head portion 51 and a tail portion 52. The head portion 51 is hooked against a lower surface 35 of the movable shaft base 36 to prevent the movable base 3 from being fallen off. The tail portion 52 of the screw rod 53 is pierced through the centering shaft hole 31 and the centering through hole 21, and is screwed and fixed in the inner screw hole of the fixing portion 541 of the fixing shaft base 54, such that the fixing base 2 and the movable base 3 are interposed between the head portion 51 and the fixing shaft base 54 and maintained to space apart an axial gap Ta each other for slight movement in an axial direction. The diameter of the tail portion 52 of the shaft rod 5 is smaller than the diameter of the centering shaft hole 31 of the movable base 3 and maintains to space apart a radial gap Tr each other, such that the movable base 3 can make slight radial movement laterally or slight coaxial rotation. Further, a bearing 6 is installed between the fixing base 2 and the movable base 3 to reduce wearing away and friction force between the fixing base 2 and the movable base 3 when in movement or rotation.

Although the present invention has been explained in relation to its preferred embodiment, it is to be understood that many other possible modifications and variations can be made without departing from the scope of the invention as hereinafter claimed.

What is claimed is:

1. A position-returning mechanism for a pick-and-place apparatus, comprising:
a fixing shaft base, including a fixing portion;
a fixing base, installed beneath the fixing shaft base, the fixing base being installed with a centering through hole, in which at least two first circular recesses are respectively concavely provided in an equal angle along an outer periphery of the centering through hole on a lower surface of the fixing base, at least two fixing blocks are respectively convexly provided in an equal angle on the lower surface of the fixing base, respectively each of the at least two fixing blocks is disposed and inserted between two adjacent first circular recesses, an axial buffer unit is provided and received in an internal part of each of the at least two fixing blocks, and the axial buffer unit is convexly extending downward to an external part of each of the axial buffer unit;
a movable base, installed with a centering shaft hole, in which at least two second circular recesses are concavely provided on an upper surface of the movable base corresponding to the at least two first circular recesses of the fixing base, at least two recessing portions are hollowed out and concavely provided at the movable base corresponding to the at least two fixing blocks of the fixing base, and the at least two recessing portions are respectively bigger than the corresponding at least two fixing blocks;
at least two ring sprig pillars, being provided and received respectively in the at least two first circular recesses and in the at least two second circular recesses; and
a shaft rod, including a head portion and a tail portion, the head portion being hooked against a lower surface of the movable base, the trail portion being pierced through the centering shaft hole and the centering through hole, and being fixed and installed on the fixing portion of the fixing shaft base, such that the fixing base and the movable base are interposed between the head portion and the fixing shaft base and maintained to space apart an axial gap each other, wherein the diameter of the tail portion of the shaft rod is smaller than the diameter of the centering shaft hole of the movable base and maintains to space apart a radial gap each other.

2. A position-relating mechanism for a pick-and-place apparatus as claimed in claim 1, wherein the shaft rod is a screw rod, the fixing portion of the fixing shaft base is an inner screw hole and the screw rod is correspondingly screwed and fixed in the inner screw hole.

3. A position-relating mechanism for a pick-and-place apparatus as claimed in claim 1, wherein each of the at least two ring spring pillars is a hollow spring pillar surrounded and joined together by a steel strip.

4. A position-relating mechanism for a pick-and-place apparatus as claimed in claim 1, wherein each of the at least two ring spring pillars is a screw spring pillar screwed and surrounded from a center by a steel strip.

5. A position-relating mechanism for a pick-and-place apparatus as claimed in claim 1, further comprising a mechanical arm, in which a lower part thereof is installed with the fixing shaft base.

6. A position-relating mechanism for a pick-and-place apparatus as claimed in claim 1, wherein a lower surface of the movable base is further installed with a guiding base and the guiding base includes at least a guiding hole.

7. A position-relating mechanism for a pick-and-place apparatus as claimed in claim 6, wherein a lower surface of the guiding base further provides a vacuum sucking head.

8. A position-relating mechanism for a pick-and-place apparatus as claimed in claim 1, further comprising at least a bearing which is installed between the fixing base and the movable base.
